(19) United States
(12) Patent Application Publication
(10) Pub. No.: US 2009/0095348 A1
(43) Pub. Date: Apr. 16, 2009

(54) Method for Producing a Solar Cell with Functional Structures and a Solar Cell Produced Thereby

(75) Inventor: WOLFGANG WEGMANN, Lappersdorf (DE)

Correspondence Address: LERNER GREENBERG STEMER LLP, P O BOX 2480, HOLLYWOOD, FL, 33022-2480, US

(73) Assignee: Wieland Electric GmbH, Bamberg (DE)

(21) Appl. No.: 12/255,252

(22) Filed: Oct. 21, 2008

Related U.S. Application Data
(63) Continuation of application No. PCT/EP2007/003514, filed on Apr. 21, 2007.

(30) Foreign Application Priority Data
Apr. 21, 2006 (DE) 102006018584.6

(51) Int. Cl. H01L 31/00; H01L 21/02

(52) U.S. Cl. 136/258; 136/261; 438/57; 257/E21.002

(57) ABSTRACT

A solar cell has a p-n-junction which is parallel to an irradiated surface, and functional structures which are located on the surface of the solar cell. In a method for producing such a solar cell, a semiconductor material is doped on both sides for forming the p-n junction and the functional structures are disposed a surface of the solar cell.

### CROSS-REFERENCE TO RELATED APPLICATIONS

This is a continuing application, under 35 U.S.C. § 120, of copending international application PCT/EP2007/003514, filed Apr. 21, 2007, which designated the United States; this application also claims the priority, under 35 U.S.C. § 119, of German patent application DE 10 2006 018 584.6, filed Apr. 21, 2006; the prior applications are herewith incorporated by reference in their entirety.

### BACKGROUND OF THE INVENTION

### Field of the Invention

The invention relates to a method for producing a solar cell, and to the solar cell produced by the method, in particular made from a crystalline semiconductor body having functional structures, in particular integrated circuits, arranged on its surface in specific regions.

Solar cells have been used successfully for many years for converting light energy into electrical energy by a photoelectric effect.

Electrical circuits can be realized in an extremely small space by use of integrated circuits. An integrated circuit (IC) is an electronic circuit composed of transistors, capacitors, resistors and inductors which is integrated completely in or on a single piece of semiconductor substrate. An integrated circuit containing a single crystal of silicon is referred to as a chip. Integrated circuits have a wide variety of areas of use, for example as a main processor in a computer, as a graphics processor for providing information for a screen display, as a memory unit for storing digital data, as a sensor for converting and processing measured values, as a signal processor for processing analog and digital signals or as a digital-to-analog or analog-to-digital converter. A processor should be understood here generally to mean a processing unit for processing analog and/or digital signals.

A common starting point for the fabrication of solar cells and integrated circuits is an identical starting material, usually silicon. This can be a giant cylindrical silicon single crystal, but also amorphous or polycrystalline silicon. Further semiconductor materials, for example germanium, can also be used during fabrication.

The process for fabricating solar cells and integrated circuits using a silicon single crystal as a starting material is described below by way of example. The silicon single crystal is produced from a silicon melt for example according to the Czochralski method or the float zone method. Both methods are explained in the textbook by Bergmann/Schäfer, Lehrbuch der Experimentalphysik Band 6, Festkörper [Textbook of Experimental Physics, volume 6, solid state physics], Walter de Gruyter Verlag, Berlin, 2005, ISBN 3110174855. Preferably, the silicon single crystal is predoped in a p-conducting fashion, for example a small amount of boron being admixed with the silicon melt. Principles of solid state physics such as are required for understanding the functioning of solar cells and integrated circuits are conveyed for example in the reference book by Ashcroft/Mermin, Solid State Physics, Thomson Learning 1976, ISBN 0030839939.

For a solar cell, rectangular slabs are cut from the silicon single crystal. These slabs, already predoped in p-conducting fashion, are preferably redoped in n-conducting fashion on one side by a diffusion process. When exposed to light therefore, a solar cells acts like a giant areal diode and generates electrically useable energy. It is provided with contacts on both surface sides and combined with further solar cells and framed to form a conductive assembly, a photovoltaic module.

For integrated circuits, circular wafers with a high dimensional accuracy of the outer contour are cut from the silicon single crystal. The dimensional accuracy of the outer contour is necessary since one fabrication step contains projecting a highly complex interconnect structure onto the silicon surface by an optical projection system. Interconnect structures are of an order of magnitude of 100 nm.

In photovoltaic power stations, many photovoltaic modules are interconnected with one another for the generation of electrical energy on a large scale. The registration of the quantity of energy generated is an important item of information here. By way of example, it is possible in this way to detect differences in the quantity of energy generated between different photovoltaic modules or combinations of photovoltaic modules which, however, must be comparable in terms of their construction. Large deviations in the quantity of energy generated indicate in particular a high degree of contamination, for example by bird excrement, or damage, for example as a result of hail. Operators of relatively large photovoltaic power stations can thus indirectly obtain information about the operating state of individual photovoltaic modules. A method for operational monitoring of a photovoltaic installation by an additional electrical circuit is known for example from published, European patent application EP 1 398 687 A2.

Since photovoltaic modules, in particular those which are mounted on remote unoccupied buildings or are situated on unsecured outdoor installations, are not secure against theft, safeguarding photovoltaic modules against theft is increasingly gaining in importance. International patent disclosure WO95/25374 discloses a solution which triggers an alarm by an additional electric circuit upon interruption of the electrical connection of a photomodule and thus enables rapid reaction to the theft.

German patent DE 199 38 199 C1, corresponding to U.S. Pat. No. 6,395,971, discloses a photovoltaic module configured for transmitting and receiving high-frequency electromagnetic waves. In this case, the electrically conductive contacts of the photovoltaic module are simultaneously used as an antenna element. The transmission and reception are effected by additionally fitted electrical circuits.

### SUMMARY OF THE INVENTION

It is accordingly an object of the invention to provide a method for producing a solar cell with functional structures and a solar cell produced thereby which overcome the above-mentioned disadvantages of the prior art methods and devices of this general type, which has extended integrated functions.

For this purpose, as already described by way of example, first a p-n junction is produced over the entire area on a semiconductor structure in accordance with the prior art. Functional structures are subsequently arranged on the surface of the solar cell. The techniques known from the production of integrated circuits are used for this purpose. The solar cell is subsequently provided with contacts on both surface sides. Regions with functional structures are omitted in this case. The solar cell is subsequently either used individually or combined and framed with further solar cells to form a conductive assembly, a photovoltaic module. The combination of the fabrication processes for solar cells and integrated circuits means that the already existing fabrication processes can be maintained largely unchanged, which leads to cost-effective production of the solar cell.

The solar cell produced according to the method according to the invention generates the electrical energy necessary for the operation of the functional structures itself. In addition, the functional structures are inseparably connected to the solar cell. This results in a very compact construction. The development of complicated additional external circuits for providing functions is obviated.

Preferably, these functional structures are integrated circuits or the combination of integrated circuits and further electrical elements such as transistors, conductors, resistors and inductors. The solar cell can be provided with additional functions in this way. Since the solar cell and the functional structures are fabricated from the same carrier material, particularly simple fabrication can be obtained via the combination of the production methods for solar cells and integrated circuits. Since, moreover, a complete wafer of a semiconductor material serves as the starting material for the solar cell, there is no compulsion for miniaturization of the integrated circuits. The integrated circuits contain only a small area proportion relative to the total area of the solar cell. Consequently, the integrated circuits can be made larger in comparison with integrated circuits which are customary nowadays. The positioning of the wafer during a photolithographic exposure method is therefore less critical in comparison. Complicated positioning methods at the front end of the exposure method are therefore unnecessary. Moreover, the larger embodiment of the structures of the integrated circuits results in a considerable decrease in rejects during production.

In one advantageous variant, an integrated circuit which generates a locatable signal is arranged on the solar cell. The locatable signal can also contain spatial coordinates which are determined from signals emitted by satellites, for example, by this or a further integrated circuit. At the location of a receiver, the instantaneous position of the solar cell can thus be determined as long as the insolation power is sufficient for this.

In the event of theft, the solar cell or a photovoltaic module into which this solar cell is incorporated is brought to a different location. If, during the theft, the insolation power does not suffice for generating a locatable signal, for example because the theft is carried out at night or else because the solar cell is provided with a covering or tarpaulin, the solar cell cannot be localized in this period of time. If, by contrast, the locatable signal is generated during the theft, an escape route of the thief can be tracked, such that measures for apprehending the thief can already be initiated at this point in time.

A renewed start-up of the solar cell or of a photovoltaic module into which such a solar cell is integrated leads, however, at any rate to the generation of the locatable signal; the solar cell can be localized by spatial information and it is possible to initiate measures for recovering the solar cell and for apprehending the thieves. For the thief, therefore, a start-up of the solar cell is always associated with the risk of his being located. A secure antitheft protection of the solar cell is therefore ensured.

For unique identification of a solar cell it is expedient to transmit with the locatable signal an identifier, for example a serial number, in order to obtain a unique item of information regarding which solar cell generated the locatable signal. Since the integrated circuit is arranged on the solar cell, removal of this circuit during theft is not possible or is possible only by spending a long time. Moreover, the thief risks damaging the solar cell or the entire photovoltaic module.

In one expedient variant, at least one integrated circuit detects operating data such as the insolation power generated by the solar cell or a photovoltaic module. The ambient temperature of the air can be calculated from the insolation power and the temperature of the solar cell. The locatable signal is provided with the measured values. These values can be processed further at the location of a receiver. The measurement of the insolation power is used indirectly, if its value decreases very greatly, for detecting damage or contamination of the solar cell. Moreover, it is possible to determine what amount of electrical energy is being generated by the solar cell. The insolation power and the ambient temperature calculated therefrom are additionally of importance meteorologically. Communicating them together with the spatial information to a meteorological institute assists for example in optimizing, on the basis of additional data, the models used for weather forecasting.

A data exchange is expediently possible between the integrated circuits arranged on the solar cell. In this way, the data measured by all the integrated circuits can be communicated to the processing unit. It is thus possible to divide different measurement tasks among different integrated circuits. Such a procedure has the advantage, in particular, that different functions can be combined according to a kit principle and there is no need to develop highly complicated integrated circuits for special tasks.

The monocrystalline semiconductor body on which the solar cell and the integrated circuits are arranged is preferably fabricated from silicon or gallium arsenide. This can involve a single crystal, a polycrystalline semiconductor body or an amorphous semiconductor body.

In one preferred configuration, one of these solar cells is part of a photovoltaic module. In this way, the functional structures can be utilized for the entire photovoltaic module. Moreover, new photovoltaic modules or assemblies of photovoltaic modules can be integrated in photovoltaic power stations in such a way that it is merely necessary to link these photovoltaic modules to a supply unit. Complicated wiring of individual solar cells can be obviated particularly with the use of a radio unit for data transmission.

Since, moreover, the solar cell with the integrated circuits is connected to the other solar cells of the photovoltaic module fixedly, for example by framing, with generation of a locatable signal a localization of the entire photovoltaic module is possible at any time in the event of theft.

Other features which are considered as characteristic for the invention are set forth in the appended claims.

Although the invention is illustrated and described herein as embodied in a method for producing a solar cell with functional structures and a solar cell produced thereby, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF SEVERAL VIEWS OF THE DRAWINGS

FIG. 1 is a diagrammatic, plan view of a photovoltaic module with an integrated solar cell according to the invention; and

FIG. 2 is a diagrammatic, plan view of a further photovoltaic module with a further solar cell according to the invention.

### DETAILED DESCRIPTION OF THE INVENTION

Functional structures having a comparable function are provided with identical reference symbols throughout the drawings. However, the functional structures may have differences in their configuration.

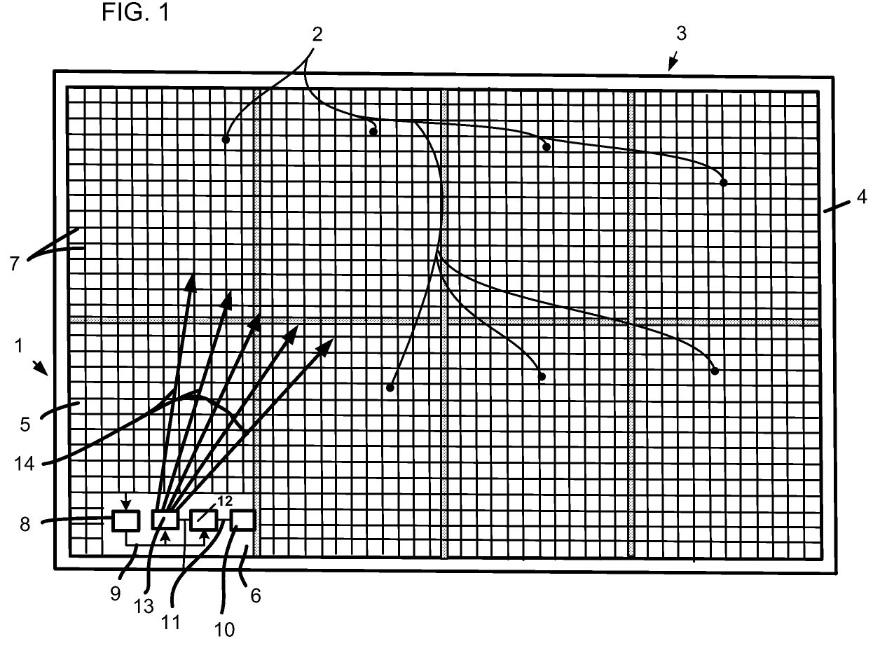

Referring now to the figures of the drawing in detail and first, particularly, to FIG. 1 thereof, there is shown a functional schematic diagram of a solar cell 1. Additional devices such as, for example, a housing as protection against weathering are not illustrated.

The solar cell 1 is integrated into an assembly of conventional solar cells 2, which in its entirety forms a photovoltaic module 3. The individual solar cells 1, 2 are held together captively by a frame 4.

Like the conventional solar cells 2, the solar cell 1 has a p-n junction 5 provided for converting light energy into electrical energy. Integrated circuits 10, 12, 13 are arranged on a region 6. The region 6 does not serve for obtaining electrical energy. Apart from the region 6, the surface of the solar cell 1 in the same way as the entire surfaces of the conventional solar cells 2 is provided with a braiding of contact-making wires 7 for tapping off the electrical energy generated by insolation.

First a supply unit 8 is arranged on the surface of the region 6, the supply unit buffer-storing the electrical energy generated by the region with the p-n junction 5 of the solar cell 1. The supply unit 8 provides electrical energy for integral circuits via supply lines 9.

The integrated circuit for insolation power and temperature measurement 10 is configured in such a way as to measure the insolation power, to calculate from this the temperature of the ambient air, and to transfer the measurement data to a processing unit 12 via a data line 11. The processing unit 12 conditions the data and transfers them together with a stored code for a serial number of the photovoltaic module 3 via a further data line 11 to an integrated circuit for generating a locatable signal 13. The latter integrated circuit generates a locatable signal 14 at periodic intervals, the signal being received by a non-illustrated receiver.

In this way, the spatial position of the photovoltaic module 3 can be detected at any time at the location of the receiver. The registering of a change in the spatial position can be equated with an unauthorized removal of the photovoltaic module and enables countermeasures to be implemented. A unique identification of the stolen photovoltaic module can be performed by the communication of the serial number. During normal operation, on the basis of the insolation power periodically communicated, it is possible to ascertain at any time whether the photovoltaic module is in a proper operating state. A relative decrease in the insolation power with respect to the values for the insolation power for adjacent photovoltaic modules is an indication of a disturbance of the operating state, for example as a result of contamination. The values for the irradiance and the air temperature of the surroundings, which values are calculated from the insolation power, are periodically communicated to a meteorological apparatus. They are incorporated into a meteorological computational model and improve a weather forecast. Particularly in sparsely populated regions such as Canada, central Australia or the Middle West of the United States or in regions having a weak infrastructure, such as in almost the whole of Africa, the weather forecast can thus be improved. Projects for electrifying regions by photovoltaic modules 3 of this type thus contribute to an improvement of the weather forecast as a secondary effect and without additional costs.

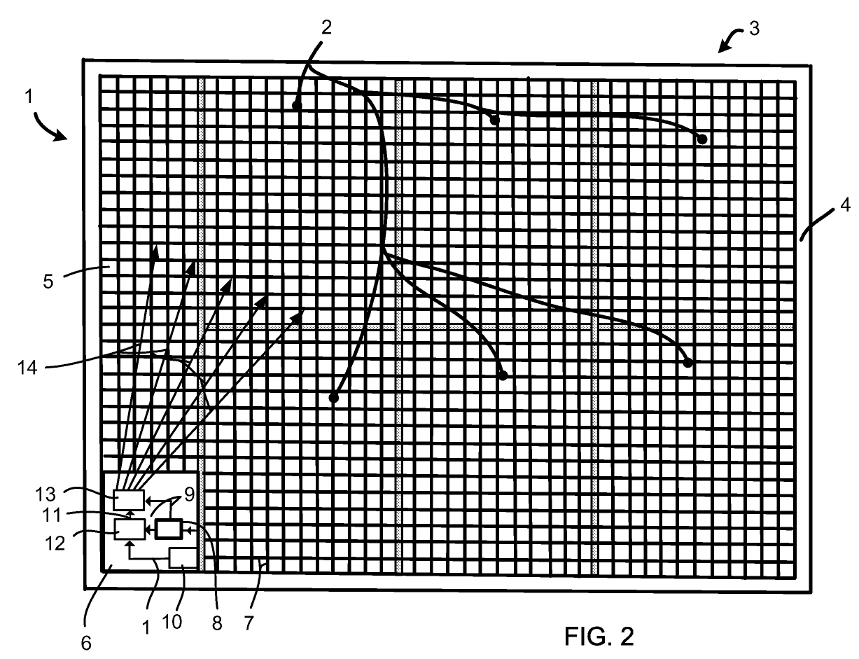

In FIG. 2, a further variant of the solar cell 1 is held together jointly with conventional solar cells 2 in a photovoltaic module 3. The solar cell 1 is in this case arranged in strip-like fashion at an end of the photovoltaic module 3.

The functional elements on the solar cell 1 according to the invention can have structural parts, for example coverings or housings of the integrated circuits. The solar cell 1 according to the invention is thus of higher construction than the conventional solar cells 2. In the case where a photovoltaic module 3 is covered with a glass such as titanium dioxide, by the arrangement of the solar cell 1 at an end of the photovoltaic module 3 it is possible in this way to implement a separate covering of the solar cell 1 according to the invention and the conventional solar cells 2.

In the case where the photovoltaic module 3 is covered with a film, by contrast, structurally governed height differences of up to 3 mm between the solar cell 1 according to the invention and conventional solar cells 2 can be compensated for. A strip-like arrangement of the solar cell 1 according to the invention, as in FIG. 2, is expedient here only when the height difference between the solar cell 1 according to the invention and the conventional solar cells 2 is above 3 mm.

1. A method for producing a solar cell, which comprises the steps of:
doping a semiconductor material on both sides for forming a p-n junction; and
providing functional structures on a surface of the solar cell.

2. A solar cell, comprising:
a semiconductor material having an irradiated surface and being doped on both sides for forming a p-n junction parallel to said irradiated surface; and
functional structures disposed on a surface of the solar cell.

3. The solar cell according to claim 2, wherein said functional structures are worked into said surface.

4. The solar cell according to claim 2, wherein said functional structures are integrated circuits.

5. The solar cell according to claim 4, wherein at least one of said integrated circuits is a circuit for generating a locatable signal.

6. The solar cell according to claim 4, wherein at least one of said integrated circuits is a circuit for detecting operating data.

7. The solar cell according to claim 2, further comprises a processing unit and at least one of said functional structures exchanges data with said processing unit.

8. The solar cell according to claim 2, wherein said functional structures are two function structures disposed on the solar cell and said two functional structures exchanging data with each other.

9. The solar cell according to claim 2, wherein said semiconductor material is a monocrystalline semiconductor body.

10. The solar cell according to claim 9, wherein said monocrystalline semiconductor body is fabricated from silicon.

11. The solar cell according to claim 9, wherein said monocrystalline semiconductor body is fabricated from gallium arsenide.

12. The solar cell according to claim 2, wherein said semiconductor material is a polycrystalline semiconductor body.

13. The solar cell according to claim 2, said semiconductor material is an amorphous semiconductor body.

14. The solar cell according to claim 2, wherein said semiconductor material having said irradiated surface and being doped on both sides forming said p-n junction and said functional structures form part of a photovoltaic module.

15. The solar cell according to claim 4, wherein at least one of said integrated circuits is a circuit for detecting insolation power generated by the solar cell.
